(19) United States
(12) Patent Application Publication
(10) Pub. No.: US 2019/0074358 A1
(43) Pub. Date: Mar. 7, 2019

(54) Semiconductor Device Comprising Diamond and Method For Its Manufacturing

(71) Applicant: Fraunhofer-Gesellschaft Zur Förderung Der Angewandten Forschung E.V., Munich (DE)

(72) Inventors: Verena Zürbig, Freiburg (DE); Christoph E. Nebel, Freiburg (DE)

(21) Appl. No.: 15/697,743

(22) Filed: Sep. 7, 2017

(51) Int. Cl. H01L 29/16; H01L 29/66; H01L 29/06; H01L 29/47; H01L 29/812

(52) U.S. Cl. CPC H01L 29/1602; H01L 29/66015; H01L 29/812; H01L 29/47; H01L 29/66893; H01L 29/0619

(57) ABSTRACT

Hot metal dissolution of carbon atoms is used to structure a diamond substrate. A layer of catalytic material is deposited on at least a portion of a surface of the diamond substrate. The layer of catalytic material may be structured using photolithography to define a gap exposing the surface of the diamond substrate, where the gap has a (110) orientation relative to the crystal structure of the diamond substrate. The exposed surface of the diamond substrate is etched to form at least one recess having at least one (111) oriented diamond surface (facet). The catalytic material is removed by a suitable cleaning process. The (111) oriented surface is then overgrown with diamond comprising a dopant resulting in a conductivity of the overgrown diamond that is different from the conductivity of the doped substrate. The doping concentration of the overgrown diamond is greater than 10¹⁹ cm⁻³.

### FIELD OF THE DISCLOSURE

The disclosure relates to methods for structuring diamond substrates to expose (111) oriented diamond surfaces upon which highly doped diamond layers can be grown.

### BACKGROUND

Diamond is an attractive substrate for semiconductor devices because of its outstanding physical and electrical properties. FIGS. 1(a) and 1(b) illustrate a JFET with lateral p-n junctions formed on a diamond substrate. Positively doped (n+) regions necessary for device function are shown in FIG. 1(b). For some applications, doped (e.g., phosphorus-doped) diamond layers having a high doping concentration (>10¹⁹ cm⁻³) are required. However, diamond does not incorporate phosphorus (P) efficiently, making the production of highly doped diamond crystal has been difficult. It is known that phosphorus incorporation into diamond crystal strongly depends upon the substrate orientation, i.e., growth direction.

Diamond is a transparent crystal of tetrahedrally bonded carbon atoms in a covalent network lattice (sp³) that crystallizes into the diamond lattice which is a variation of the face-centered cubic structure. The natural form of a diamond crystal is an octahedron. Miller indices are used to describe how many of the three crystal axes a crystal plane may intersect. A cube plane intersects only one axis and is given the number 100 (intersecting one axis and missing two, hence 1, 0, 0 or 100). A dodecahedral plane intersects two axes and misses one and therefore has the number 110. An octahedral plane (tetrahedral plane) intersects three of the axes and has the number 111.

It is known that diamond grown on (111) oriented diamond surfaces incorporates phosphorous at a rate at least two orders of magnitude greater than diamond crystal grown on (100) oriented diamond surfaces. Etching methods have been developed for exposing (111) oriented diamond facets, so the (111) oriented diamond facets can be used to grow highly doped diamond layers necessary for some semiconductor applications.

The prior art includes the use of dry-chemical inductively coupled plasma (ICP) etching to produce trenches with approximately rectangular cross-sections in diamond substrates. These trenches are then overgrown with doped diamond layers, as shown in FIGS. 2 and 3. According to this method, (111) oriented surfaces form only during crystal growth, which allow a higher efficiency in the incorporation of the doping atoms. Prior art dry-chemical etching methods cause damage in the crystal lattice on the surface, which leads to defects in the epitaxial layer and thus to a degradation of the performance of the resulting electronic components.

Metal-catalytic etching processes can be used to expose high grade (111) oriented diamond facets on (100) oriented diamond surfaces. The prior art includes the use of nickel Ni spheres for the formation of etching pits with (111) oriented side walls as shown in FIG. 4. The etching depth is limited by forming an inverted pyramid with four (111) oriented side walls. The metal catalytic etching process takes place under hydrogen atmosphere at a flow rate of 100 sccm, a pressure of 500 mbar, and at temperatures above 700° C. Hydrogen (H₂) reacts with carbon (C) atoms at the interface between the metal and the diamond to form CHₓ molecules, which pass into the gas phase, resulting in etched pits having (111) oriented side walls as shown in FIG. 5.

There is a need in the art for non-plasma processes for etching diamond.

There is a need in the art for processes for etching diamond to expose (111) oriented diamond facets having less defects and improved flatness.

There is a need in the art for cost effective process for etching diamond to form arbitrarily large (111) oriented, defect free surfaces in (100) oriented diamond substrates.

### SUMMARY OF THE INVENTION

According to aspects of the disclosure, metal-catalytic etching of (100) oriented diamond surfaces can be used to expose trenches having (111) oriented diamond faces, which can be selectively overgrown with doped diamond layers. For this purpose, metals (e.g., Ni or Cr) with a layer thickness of approximately 200 nm are patterned (e.g., with photolithography) onto a (100) oriented diamond surface. The metal structures must be aligned along the (110) orientation of the diamond substrate. Etching takes place at 700°-900° under a hydrogen (H₂) atmosphere. After etching, the metal can be removed by a suitable cleaning process.

For the purpose of this disclosure, “diamond substrate” includes any piece of a diamond, epitaxial, homoepitaxial, or heteroepitaxial deposited diamond layer. A method for structuring a diamond substrate having a (100) oriented surface according to aspects of the disclosure comprises: depositing a layer of catalytic material on the (100) oriented diamond surface of the diamond substrate; structuring the catalytic layer to expose the (100) oriented diamond surface; and etching the (100) oriented diamond surface at an elevated temperature in a hydrogen atmosphere to form a recess in the (100) oriented diamond surface, the recess having at least one (111) oriented diamond facet.

According to one embodiment of the disclosed method, the diamond surface is etched using a metal-catalytic etching process performed at temperatures above 700° C. in a hydrogen atmosphere. Preferably, the metal-catalytic process takes place at temperatures between 700° C. and 950° C. This temperature may be obtained in a furnace within which the diamond substrate is placed. More preferably, the metal-catalytic etching process takes place at temperatures between 800° C. and 950° C. The catalytic material may be nickel (Ni) or chromium (Cr), or an alloy of nickel (Ni) and chromium (Cr). The catalytic layer is preferred to have a thickness between 80 nm and 400 nm, and more preferably a thickness of approximately 200 nm. The hydrogen atmosphere preferably has a pressure between 400 mbar and 600 mbar. The hydrogen atmosphere is maintained by a flow of hydrogen having a flow rate of between 80 sccm (standard cubic centimeters per minute) and 200 sccm.

According to aspects of the disclosure, the layer of catalytic material is structured into at least first and second polygonal areas separated by at least one gap. The gap is oriented in a (110) direction on the (100) oriented diamond surface. Diamond substrate is etched beneath the catalytic layer, exposing a (111) oriented surface (facet) between the exposed diamond substrate (which is not etched) and the etched (100) oriented surface beneath the catalytic layer. As the diamond substrate is etched, the catalytic layer descends relative to a surface of the diamond substrate that is not covered with the catalytic layer. The binding energy of atoms in the (111) orientation is stronger than in the (100) orientation, with the result that the (100) oriented surface covered with catalytic material descends into the diamond substrate, revealing a (111) oriented surface (facet) along the edge of the catalyst layer. After high temperature processing in a hydrogen atmosphere, the catalytic layer is removed. The result is a three dimensional structured surface having a (111) oriented surface (facet) connecting two (100) oriented surfaces.

According to aspects of the disclosure, the diamond substrate may comprise diamond and a dopant resulting in a diamond substrate having a first conductivity. A layer of catalytic material is deposited on at least a portion of a surface of the diamond substrate. The layer of catalytic material is structured to expose the surface of the diamond substrate. The layer of catalytic material may be structured using photolithography to define a gap exposing the surface of the diamond substrate, where the gap has a (110) orientation relative to the crystal structure of the diamond substrate. The surface of the diamond substrate that is not covered with catalytic material is not etched. The surface of the diamond substrate beneath the catalytic material is etched and recedes to form at least one recess having at least one (111) oriented diamond surface (facet) along the edge of the area of catalytic material. The catalytic material is removed by a suitable cleaning process to reveal a three dimensionally structured substrate having (100) oriented surfaces connected by a (111) oriented surface (facet). The (111) oriented surface is then overgrown with diamond comprising a dopant resulting in a conductivity of the overgrown diamond that is different from the conductivity of the doped substrate. The doping concentration of the overgrown diamond is greater than 10¹⁹ cm⁻³.

### BRIEF DESCRIPTION OF THE DRAWINGS

FIG. 1(a) illustrates a JFET with lateral P-N junction formed on a diamond substrate;

FIG. 1(b) is a drawing of a sectional view through the JFET structure of FIG. 1(a) taken along line A-A, illustrating the relative position and form of materials making up the JFET of FIG. 1(a);

FIGS. 2 and 3 illustrate steps and material configurations in a prior art method of forming doped (n+) materials on a diamond substrate;

FIG. 4 illustrates the form of an etching pit in a (100) oriented diamond surface by anisotropic etching by molten Ni particles as known in the prior art;

FIG. 5 illustrates a process for metal catalytic structuring of diamond surfaces;

FIG. 6 is an image of a pattern of polygonal areas of catalytic material on a diamond substrate according to aspects of the disclosure;

FIG. 6A is a partial sectional view through the diamond substrate and areas of catalytic material of FIG. 6, with the dimensions exaggerated for clarity;

FIG. 7 is an enlarged view of the edge of one area of catalytic material and diamond substrate of FIG. 6, showing the adjacent exposed surface of the diamond substrate before etching;

FIG. 8 is an image of the polygonal areas of catalytic material and diamond substrate after etching;

FIG. 8A is a partial sectional view through the diamond substrate and areas of catalytic material of FIG. 8, with the dimensions exaggerated for clarity;

FIG. 9 is an enlarged view of the intersection of catalytic material and diamond substrate of FIG. 8;

FIG. 10 is a further enlarged view of diamond surfaces formed by catalytic etching of the diamond substrate of FIGS. 8 and 9;

FIG. 10A is a partial sectional view through a diamond substrate after structuring by a method according to aspects of the disclosure;

FIG. 11 is a graphical presentation of measurements taken along line B in FIG. 12, showing the dimensions and position of a (111) oriented diamond surface produced according to the disclosed method;

FIG. 12 is an alternative graphical presentation of measurements showing the relative position of the (111) and (100) oriented surfaces produced by the disclosed structuring method;

FIG. 13 is a graphical presentation of data showing the flatness of the (111) surface produced by the disclosed structuring method; and

FIG. 14 is a sectional view through a Schottky diode with (n+) doped material grown on (111) oriented diamond surfaces in a (p−) doped diamond substrate, where the (111) oriented surfaces are produced by the disclosed structuring method.

### DETAILED DESCRIPTION

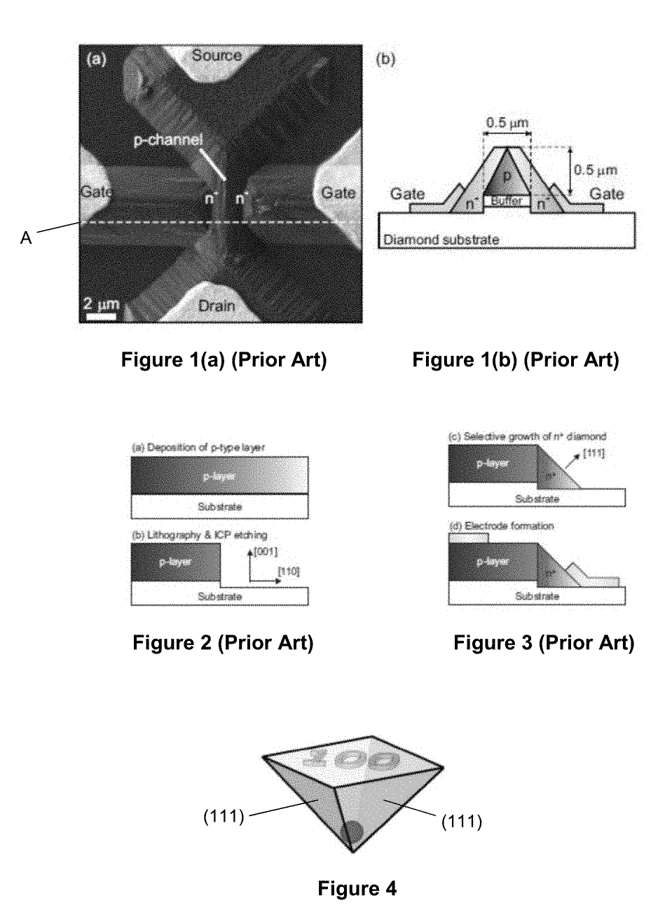

FIGS. 1(a) and 1(b) illustrate a prior art JFET semiconductor device constructed on a diamond substrate, where the diamond substrate has been structured according to prior art methods. Prior art structuring methods such as inductively coupled plasma (ICP) etching applied to a (100) oriented diamond surface produced (001) and (110) oriented surfaces as shown in FIG. 2. FIG. 3 illustrates n+ doped diamond material grown in the space between the (001) and (110) oriented surfaces, resulting in a (111) oriented, n+ doped region having a conductivity different than the adjacent P-layer and substrate.

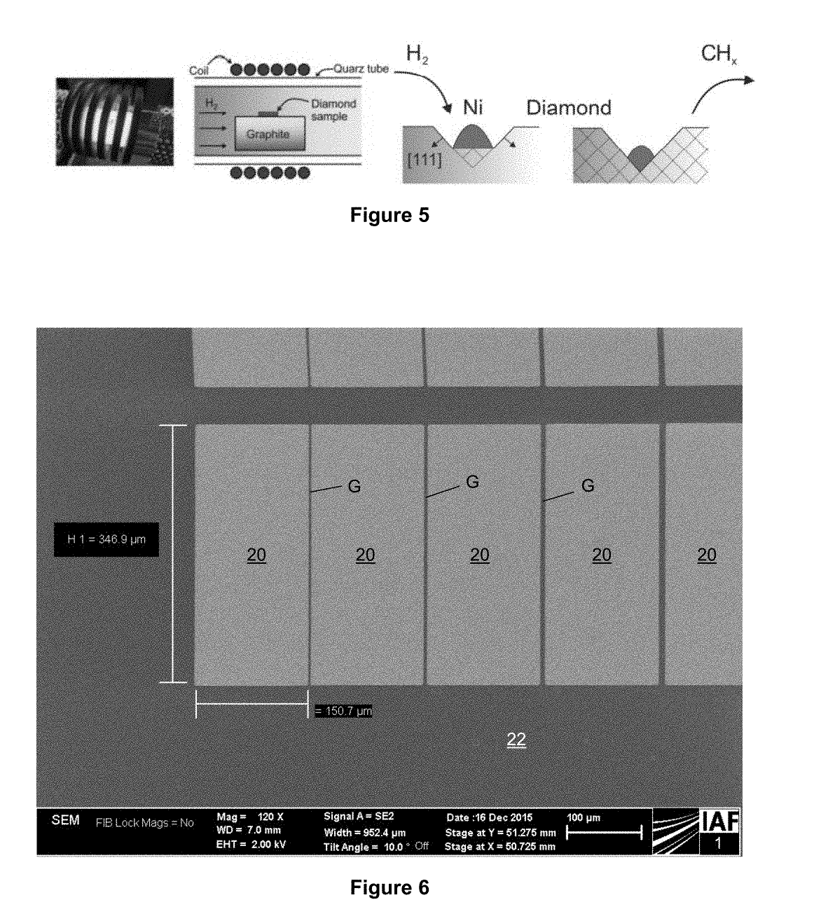

FIG. 4 illustrates (111) oriented surfaces produced by hot metal dissolution of carbon atoms according to a method referred to as “catalytic etching.” When exposed to temperatures greater than 700 sphere of catalytic metal such as Nickel (Ni) enhances the formation of hydrocarbon (CHₓ) molecules which pass into the gas phase and erode the diamond substrate. FIG. 4 illustrates a pit having four (111) oriented surfaces formed adjacent to a Ni sphere on a diamond substrate after high temperature processing in a hydrogen atmosphere. FIG. 5 illustrates a furnace having a quartz tube for heating a diamond substrate in a hydrogen atmosphere, and shows the consumption of a catalytic metal (Ni) and erosion of diamond substrate beneath the catalytic metal to form (111) oriented surfaces.

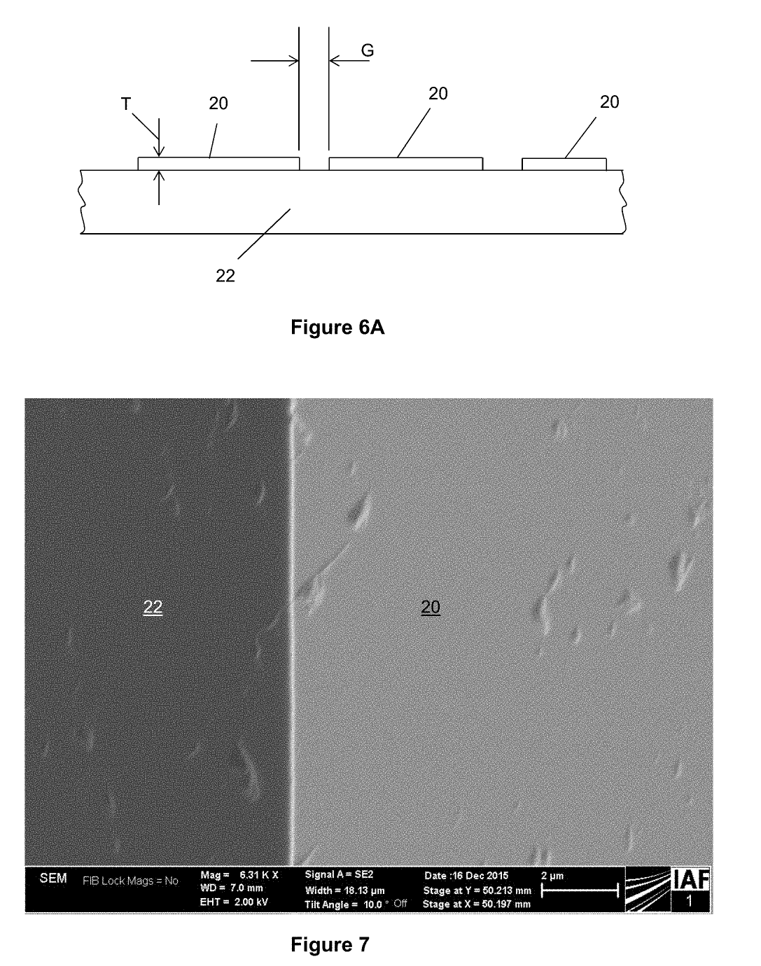

FIG. 6 is an image of rectangles of catalytic material 20 approximately 347 μm×151 μm on a 100 oriented surface of a diamond substrate 22 according to aspects of the disclosure. Other polygonal shapes may be used. The rectangles (or other polygonal shapes) of catalytic material 20 may be produced from a continuous layer by photolithography as is known in the art. The catalytic material has a thickness T between 80 nm and 400 nm, with a preferred thickness of approximately 200 nm. The polygonal shapes are arranged on the substrate 22 with gaps between adjacent sides of the polygons where the diamond substrate 22 is exposed. The gap is oriented in a (110) direction with respect to the crystal structure of the diamond substrate. The gap has a lateral dimension G that varies from 3 μm-32 μm. FIG. 6A is a partial sectional view through the areas of catalytic material 20 and diamond substrate 22 of FIG. 6, with the dimensions exaggerated for clarity. FIG. 7 is an enlarged image of one edge of a polygon of catalytic metal and the adjacent exposed diamond substrate.

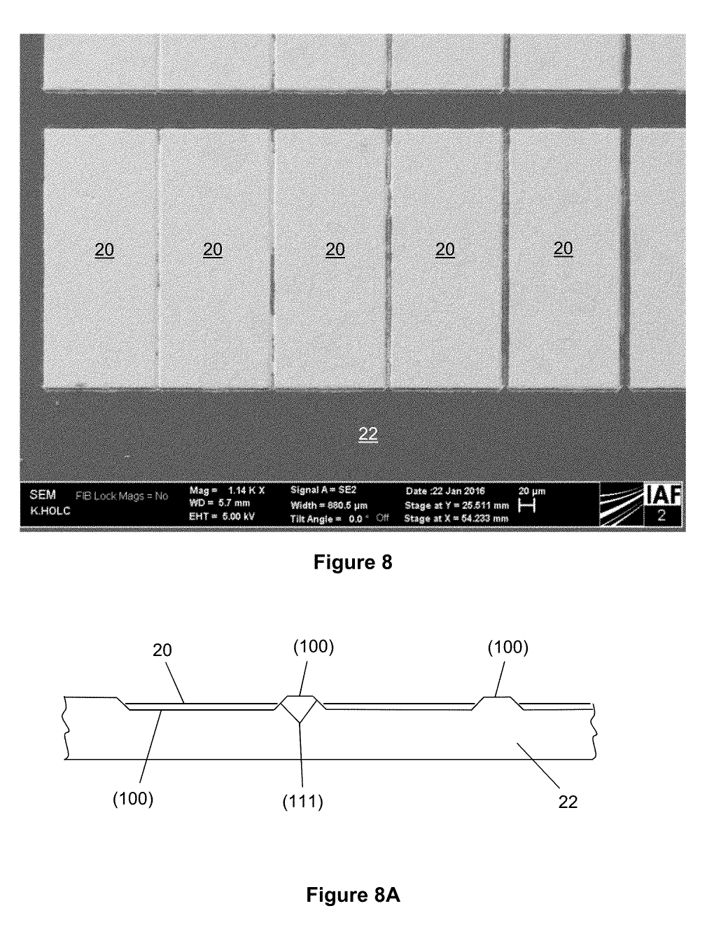

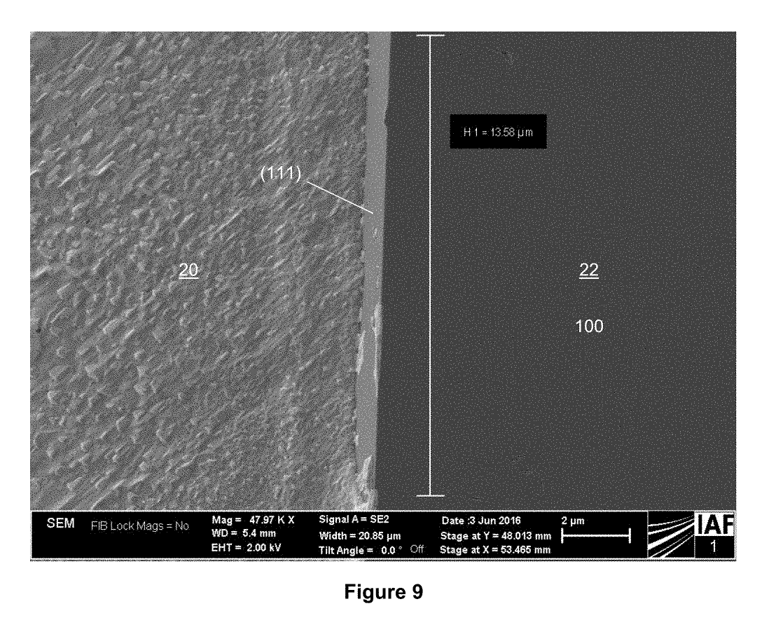

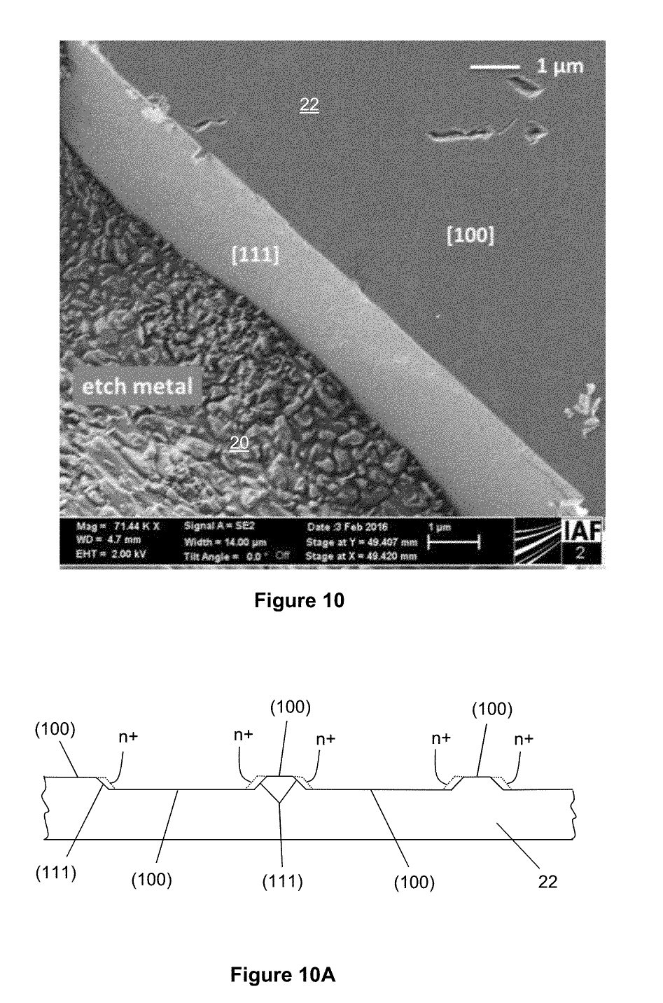

FIG. 8 is an image of the diamond substrate and polygons of catalytic metal after high temperature treatment (annealing) in a hydrogen atmosphere. FIG. 8A is a partial sectional view through the diamond substrate 22 and areas of catalytic material (dimensions are exaggerated for clarity), showing the etching (recession) of the diamond substrate 22 beneath the catalytic material and the resulting (111) oriented surfaces (facets). It will be apparent that the shape and arrangement of the areas of catalytic material 20 on the diamond substrate 22 determine the position of the resulting (111) oriented surfaces (facets). FIGS. 9 and 10 are enlarged images of a portion of the diamond substrate of FIG. 8, showing a (111) oriented surface produced by the disclosed structuring method. The diamond substrate is etched (eroded) adjacent the catalytic metal to produce the (111) oriented surface. The catalytic etching takes place at temperatures greater than 700° C. in a hydrogen atmosphere, and preferably greater than 850° C.

FIG. 10A is a partial sectional view through the diamond substrate 22 after removal of the catalytic material, revealing the resulting three dimensional structured surface, including (111) oriented surfaces between (100) oriented surfaces. Areas of highly n+ doped material can then be grown on the (111) oriented surfaces.

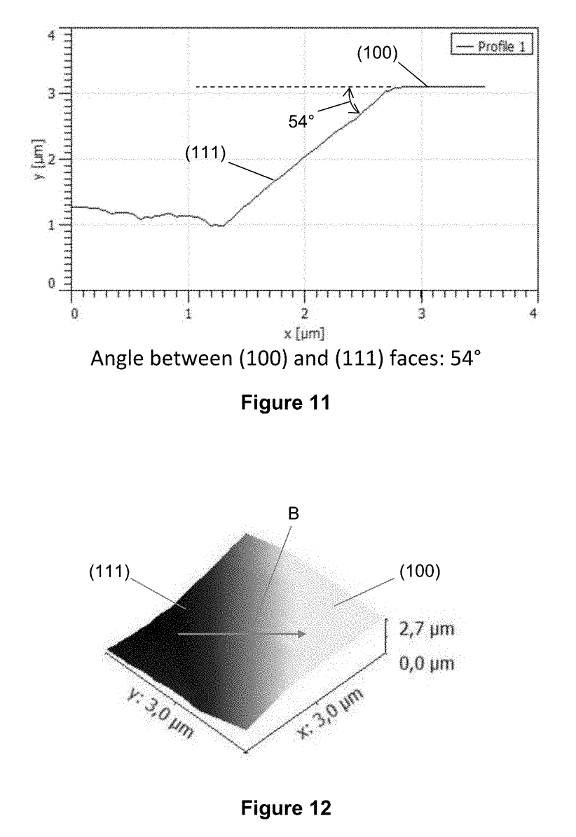

Measurements taken by scanning electron microscope (SEM) and atomic force microscopy (AFM) show that the resulting (111) oriented surface is very flat, with low rates of defect, which makes the (111) oriented surface ready for efficient, selective n-type i.e., phosphorous doped chemical vapor deposition (CVD) overgrowth. FIG. 12 illustrates an enlarged portion of a substrate 22 structured according to the disclosed method. FIG. 11 graphically presents measurements taken along line B of FIG. 12, and shows the angular relationship between the (111) oriented surface and the (100) oriented surface. The angle between the (111) oriented surface and the (100) oriented surface is approximately 54°.

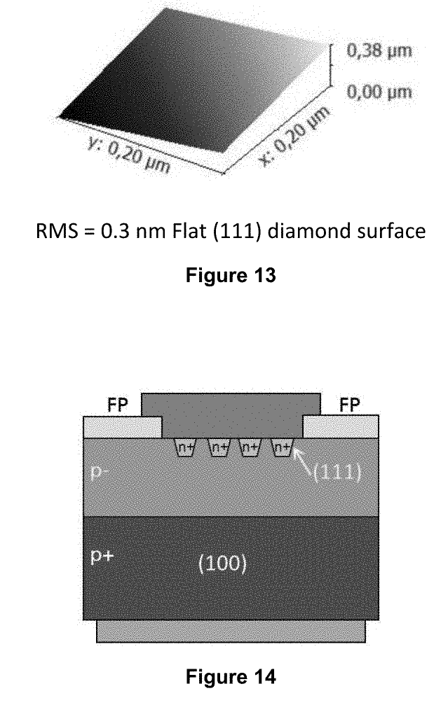

FIG. 13 illustrates an enlarged portion of the (111) oriented surface produced by the disclosed method. Measurements taken by atomic force microscopy show that the (111) oriented surface is very flat, having a deviation of 0.3 nm RMS. The flatness of a (111) and (100) oriented surfaces produced according to the disclosed method is superior to surface properties produced by other structuring methods.

FIG. 14 is a sectional view through a Schottky diode constructed on a diamond substrate structured according to the disclosed method. A p− doped diamond layer is structured according to the disclosed methods to produce wells having (111) oriented surfaces. The wells are overgrown with n+ doped material, where the n+ doped material has a doping concentration of greater than 10¹⁹ cm⁻³. Boron is used for the p-type doping and phosphorus is used as doping material for the n+ doping. The Ohmic contact beneath the diamond substrate consists of Ti/Pt/Au and the Schottky contact covering the n+ doped trenches is constructed of, for example of Mo, Pt, Ti, etc.

The shape of the cavities formed according to the disclosed method is not limited to a particular shape. Whatever their shape, the recessed areas will include (111) oriented faces suitable for overgrowth with highly doped n+ diamond material. In a Schottky diode illustrated in FIG. 14, the typical concentrations and layer thicknesses are:

p+: 300 μm: 10²⁰ cm⁻³

p−: 1-10 μm: 10¹⁴-10¹⁶ cm⁻³

n+: 10¹⁹-10²⁰ cm⁻³

FP: field plate, B. Al₂O₃, SiₓN_{y}, SiOₓ

The size, shape, depth and doping concentration of the n+ material will be selected to meet the specifications of the semiconductor device to be produced.

What is claimed:

1. A semiconductor device, comprising
a substrate comprising at least diamond and at least a first dopant resulting in a first conductivity and having a first surface having a [100] orientation and;
at least one recess arranged on said first surface, said recess having at least one diamond facet having an [111] orientation;
a homoepitaxially grown diamond material comprising a second dopant resulting in a second conductivity and being arranged at least partially on said at least one diamond facet.

2. A device according to claim 1, comprising a Schottky contact being arranged on said homoepitaxially grown diamond material.

3. A device according to claim 1, comprising an Ohmic contact being arranged on a second surface of said substrate, said second surface being located opposite said first surface.

4. A device according to claim 1, wherein said substrate is composed of at least two layers of diamond material being arranged one above the other, both layers having the first conductivity and different concentrations of dopants.

5. A method for structuring a diamond surface, said method comprising the following steps:
providing a substrate comprising at least diamond and having a first surface;
depositing a layer of catalytic material at least on a first subarea of the first surface;
structuring said layer of catalytic material, thereby exposing the diamond in second subareas;
etching the first surface of the substrate.

6. The method according to claim 5, wherein said first surface has a [100]-orientation.

7. The method according to claim 5, wherein etching of the first surface of the substrate is carried out at an elevated temperature in a hydrogen atmosphere.

8. The method according to claim 7, wherein said elevated temperature is between 800° C. and 950° C.

9. The method according to claim 7, wherein the hydrogen atmosphere has a pressure between 400 mbar and 600 mbar.

10. The method according to claim 7, wherein a flow of hydrogen is selected between 80 sccm and 200 sccm.

11. The method according to claim 5, wherein said layer of catalytic material has a thickness between 80 nm and 400 nm.

12. The method according to claim 5, wherein said layer of catalytic material comprises any of nickel, chrome, and an alloy comprising any of nickel and chrome.

13. The method according to claim 5, wherein a recess having at least one [111]-facet of diamond is etched out of said substrate.

14. The method according to claim 5, wherein structuring said layer of catalytic material involves generating at least first and second spots of polygonal shape being separated by at least one gap.

15. The method according to claim 14, wherein said gap is oriented in [110] direction on said first surface.

16. A method for structuring a diamond surface, said method comprising the following steps:
providing a substrate having a first surface and comprising at least diamond and a dopant resulting in a first conductivity;
depositing a layer of catalytic material at least on a subarea of the first surface;
structuring said layer of catalytic material, thereby exposing the diamond;
etching the first surface of the substrate, thereby forming at least one recess having at least one [111] oriented diamond facet;
removing said layer of catalytic material.

17. The method according to claim 16, wherein said first surface has a [100]-orientation, and wherein structuring said layer of catalytic material involves generating at least first and second spots of polygonal shape being separated by at least one gap, and said gap is oriented in [110] direction relative to a crystal structure of said substrate.

18. The method according to claim 16, wherein etching of the first surface of the substrate is carried out at an elevated temperature being selected between 800° C. and 950° C. in a hydrogen atmosphere having a pressure between 400 mbar and 600 mbar.

19. The method according to claim 16, wherein said layer of catalytic material has a thickness between 80 nm and 400 nm.

20. The method according to claim 16, wherein said layer of catalytic material comprises any of nickel, chrome, and an alloy comprising any of nickel and chrome.

21. The method according to claim 16, further comprising a step of homoepitaxial growth of diamond comprising a dopant resulting in a second conductivity on said at least one (111) oriented diamond facet.
